(19) United States
(12) Patent Application Publication
(10) Pub. No.: US 2015/0368830 A1
(43) Pub. Date: Dec. 24, 2015

(54) ONE-PIECE INJECTOR ASSEMBLY AND ONE-PIECE EXHAUST LINER

(71) Applicant: Applied Materials, Inc., Santa Clara, CA (US)

(72) Inventors: Paul BRILLHART, Pleasanton, CA (US); Kin Pong LO, Fremont, CA (US); Edric TONG, Sunnyvale, CA (US); Satheesh KUPPURAO, San Jose, CA (US); Balasubramanian RAMACHANDRAN, Santa Clara, CA (US)

(21) Appl. No.: 14/737,974

(22) Filed: Jun. 12, 2015

Related U.S. Application Data
(60) Provisional application No. 62/015,225, filed on Jun. 20, 2014.
(60) Provisional application No. 62/013,978, filed on Jun. 18, 2014.

(51) Int. Cl. C30B 25/14; C30B 25/08

(52) U.S. Cl. CPC C30B 25/14; C30B 25/08

(57) ABSTRACT

Embodiments of the disclosure relate to a one-piece injector assembly. The injector assembly includes a plurality of channels for introducing process gas into a processing chamber while keeping the gas flow of each channel separate from the gas flow in each other channel. In addition, embodiments of the disclosure relate to upper and lower liners accommodating the one-piece injector assembly, methods for installing the injector assembly, and a processing chamber utilizing the one-piece injector assembly.

### CROSS-REFERENCE TO RELATED APPLICATIONS

This application claims benefit of U.S. provisional patent application Ser. No. 62/013,978, filed Jun. 18, 2014, and U.S. provisional patent application Ser. No. 62/015,225, filed Jun. 20, 2014, which are herein incorporated by reference.

### BACKGROUND

1. Field

Embodiments of the present disclosure generally relate to reduced-pressure processing techniques. More particularly, embodiments of the present disclosure relate to a one-piece injector assembly for directing the flow of process gases into a reduced-pressure processing system.

2. Description of the Related Art

Semiconductor substrates are processed for a wide variety of applications, including the fabrication of integrated devices and microdevices. One technique for processing substrates includes exposing the substrate to gases at reduced pressures and causing the gases to deposit a material, such as dielectric material or a conductive metal, on a surface of the substrate. For example, epitaxy is a deposition process that may be used to grow a thin, high-purity layer, usually of silicon or germanium, on a surface of a substrate (e.g., a silicon wafer). The material may be deposited in a cross-flow chamber by flowing a process gas (e.g., a mixture of precursor gases and carrier gases) parallel to, and across, the surface of a substrate positioned on a support, and decomposing (e.g., by heating the process gas to high temperatures) the process gas to deposit a material from the process gas onto the surface of the substrate.

The quality of the deposited film in epitaxy is directly affected by the precision with which gas flows and temperature are controlled in a process chamber. Flow control and temperature control are affected by the design of the process chamber, including the design of one or more liner rings, injectors, injector assemblies, and exhaust ports. Flow of the process gases may be controlled to allow the flow rate of process gas across the substrate to differ on different pathways (e.g., flow rate may be faster within a central pathway than within pathways near edges of a substrate), in order to improve thickness uniformity of the deposited layer across the entire substrate.

To control the relative flow rates of process gas having different flow rates on different paths across the substrate to affect the thickness uniformity of the deposited film, there is a need for a one-piece injector assembly with isolation between separate process gas pathways therethrough.

### SUMMARY

An injector assembly is provided. The injector assembly generally comprises a one piece construct configured with multiple independently controllable channels therethrough by which one or more fluids may be flowed therethough and into a reduced-pressure processing chamber.

A lower liner for a reduced-pressure processing chamber is provided. The lower liner generally includes a ring-shaped body configured with a portion removed therefrom to accommodate an injector assembly and a portion cut-away therefrom to allow rotation of the lower liner during installation of the lower liner and the injector assembly in the reduced-pressure processing chamber.

An upper liner for a reduced-pressure processing chamber is provided. The upper liner generally includes a ring-shaped body configured with a portion thereof cut-away to accommodate an injector assembly and a thicker portion configured to line a region of the processing chamber adjacent to the cut-away portion of a lower liner.

A method for installing a one-piece injector assembly in a reduced-pressure processing chamber is provided. The method generally includes rotating a lower liner of the reduced-pressure processing chamber to align a first portion cut-away from the lower liner with an injection cap of the reduced-pressure processing chamber, inserting the one-piece injector assembly through the first portion cut-away from the lower liner and into contact with the injection cap of the reduced-pressure processing chamber, rotating the lower liner to align the first portion cut-away from the lower liner with a loading port of the reduced-pressure processing chamber, and inserting an upper liner into the reduced-pressure processing chamber while simultaneously aligning a first portion cut-away from the upper liner with the one-piece injector assembly, a thicker portion of the upper liner with the first portion cut-away from the lower liner, and a second portion cut-away from the upper liner with a second portion cut-away from the lower liner.

An exhaust liner is provided. The exhaust liner generally comprises a one-piece construct configured with a channel therethrough by which one or more fluids may flow therethough and exit a reduced-pressure processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIGS. 1A and 1B illustrate sectional views of a reduced-pressure processing chamber, according to aspects of the present disclosure.

FIGS. 2A and 2B illustrate isometric views of an exemplary one-piece injector assembly, according to aspects of the present disclosure.

FIG. 2C illustrates a sectional view of an exemplary one-piece injector assembly, according to aspects of the present disclosure.

FIGS. 3A and 3B illustrate isometric views of an exemplary upper liner, according to aspects of the present disclosure.

FIGS. 4A and 4B illustrate isometric views of an exemplary lower liner, according to aspects of the present disclosure.

FIGS. 5A and 5B illustrate isometric views of an exemplary one-piece exhaust liner, according to aspects of the present disclosure.

FIG. 6 illustrates a sectional view of a one-piece injector assembly, an upper liner, a lower liner, and a one-piece exhaust liner, according to aspects of the present disclosure.

FIG. 7 illustrates an exemplary operation for installing a one-piece injector assembly into a process chamber, according to aspects of the present disclosure.

FIG. 8 illustrates an exemplary operation for performing epitaxy in a process chamber using a one-piece injector assembly, according to certain aspects of the present disclosure.

To facilitate understanding, identical reference numerals have been used, where possible, to designate identical elements that are common to the figures. It is contemplated that elements disclosed in one embodiment may be beneficially utilized in other embodiments without specific recitation.

### DETAILED DESCRIPTION

Methods and apparatuses for controlling and directing flow of process gases into a processing chamber are provided. The methods and apparatuses enable introduction of process gases into a processing chamber in a manner allowing the process gases to flow across a substrate within the processing chamber in a plurality of parallel pathways.

One embodiment disclosed herein is a gas inlet mechanism consisting of a one-piece injector assembly with multiple independent flow channels extending therethrough in isolation from one another.

In another embodiment, a lower liner of a processing chamber includes a portion thereof cut-out to accommodate an injector assembly and a second portion thereof cut-out to allow rotation of the lower liner past the injector assembly during installation of the lower liner and the injector assembly in the reduced-pressure process chamber.

In another embodiment, an upper liner of a processing chamber includes a portion thereof cut-out to accommodate an injector assembly and a thicker portion configured to line an area of the process chamber adjacent to a cut-out portion of a lower liner.

In another embodiment, a method is provided to install an injector mechanism in a processing chamber by rotating a lower liner of the processing chamber such that a first portion cut-away from the lower liner is aligned with an injection cap of the processing chamber, inserting the injector mechanism through the first portion cut-away from the lower liner and into contact with the injection cap of the processing chamber, rotating the lower liner to align the first portion cut-away from the lower liner with a loading port of the processing chamber, and inserting an upper liner into the processing chamber while simultaneously aligning a first portion cut-away from the upper liner with the one-piece injector assembly, a thicker portion of the upper liner with the first portion cut-away from the lower liner, and a second portion cut-away from the upper liner with a second portion cut-away from the lower liner.

In another embodiment, a method is provided to flow process gases into a processing chamber through separate channels of a one-piece injector assembly.

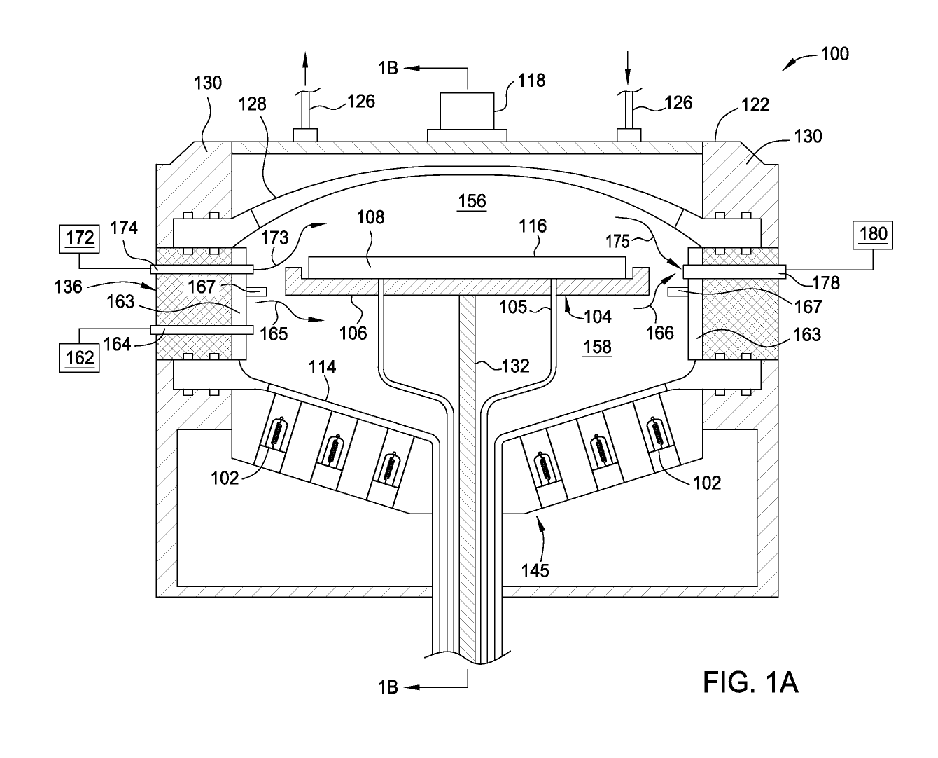

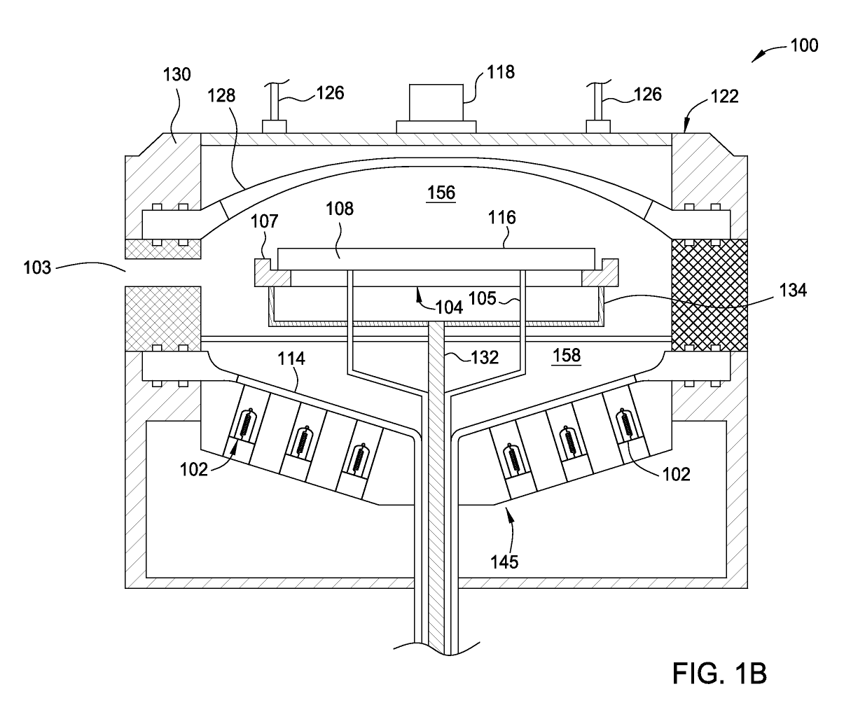

FIG. 1A illustrates a schematic sectional view of a processing chamber 100 with components in position for processing, according to aspects of the present disclosure. The processing chamber 100 and the associated hardware are preferably formed from one or more process-compatible materials, such as stainless steel, quartz (e.g., fused silica glass), silicon carbide (SiC), CVD-coated SiC over graphite (30-200 microns), and combinations and alloys thereof, for example. The processing chamber 100 is used to process (e.g., perform epitaxial deposition on) one or more substrates, including the deposition of a material on an upper surface of a substrate 108. The processing chamber 100 includes an array of radiant heating lamps 102 for heating, among other components, a back side 104 of a substrate support 106 (e.g., a susceptor) disposed within the processing chamber 100. In some embodiments, an array of radiant heating lamps is disposed over the upper dome 128 in addition to the array shown below the lower dome. The substrate support 106 may be a disk-like substrate support 106 with no central opening as shown, or may be a ring-like substrate support.

FIG. 1B illustrates a schematic side view of the processing chamber 100 taken along line 1B-1B in FIG. 1A. The liner assembly 163 and the circular shield 167 have been omitted for clarity. The substrate support may be a disk-like substrate support 106 as shown in FIG. 1A, or may be a ring-like substrate support 107, which supports the substrate from the edge of the substrate to facilitate exposure of the substrate to the thermal radiation of the lamps 102, as shown in FIG. 1B.

Referring to FIGS. 1A and 1B, the substrate support 106 or 107 is located within the processing chamber 100 between an upper dome 128 and a lower dome 114. The upper dome 128, the lower dome 114, and a base ring 136 that is disposed between the upper dome 128 and lower dome 114 define an internal region of the processing chamber 100. In general, the central portions of the upper dome 128 and of the lower dome 114 are formed from an optically transparent material, such as quartz. The internal region of the processing chamber 100 is generally divided into a process region 156 and a purge region 158.

The substrate 108 (not to scale) can be brought into the processing chamber 100 through a loading port 103 and positioned on the substrate support 106. The loading port 103 is obscured by the substrate support 106 in FIG. 1A, but can be seen in FIG. 1B.

According to one embodiment, the substrate support 106 is supported by a central shaft 132, which may directly support the substrate support 106 as shown in FIG. 1A. According to another embodiment, the central shaft 132 supports a disk-like substrate support 107 by means of arms 134, as shown in FIG. 1B.

According to one embodiment, the processing chamber 100 also comprises a lamphead 145, which supports the array of lamps 102 and cools the lamps 102 during and/or after processing. Each lamp 102 is coupled to an electrical distribution board (not shown), which supplies electricity to each lamp 102.

A circular shield 167, which may be a preheat ring, may be optionally disposed around the substrate support 106 and surrounded by a liner assembly 163. The circular shield 167 prevents or reduces leakage of heat and or light noise from the lamps 102 to the device side 116 of the substrate 108 while providing a pre-heat zone for the process gases. The circular shield 167 is made from chemical vapor deposited (CVD) SiC, sintered graphite coated with SiC, grown SiC, opaque quartz, coated quartz, or any similar, suitable material that is resistant to chemical breakdown by process and purging gases.

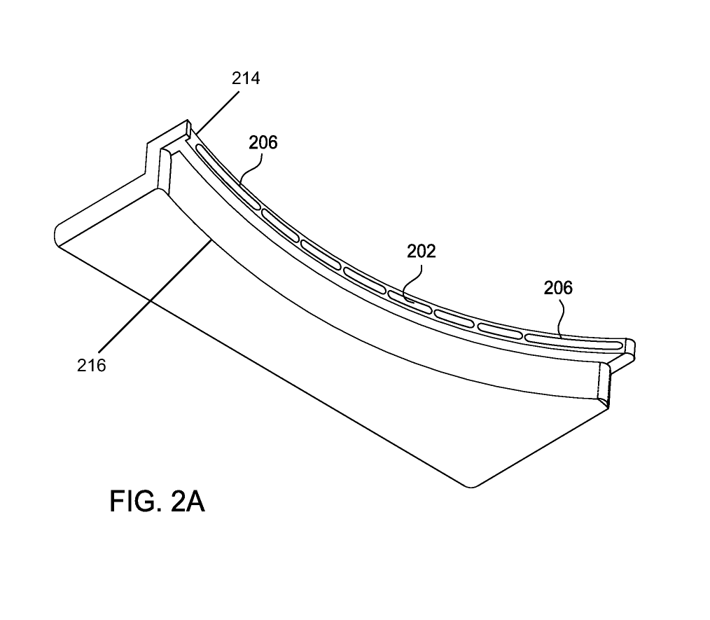

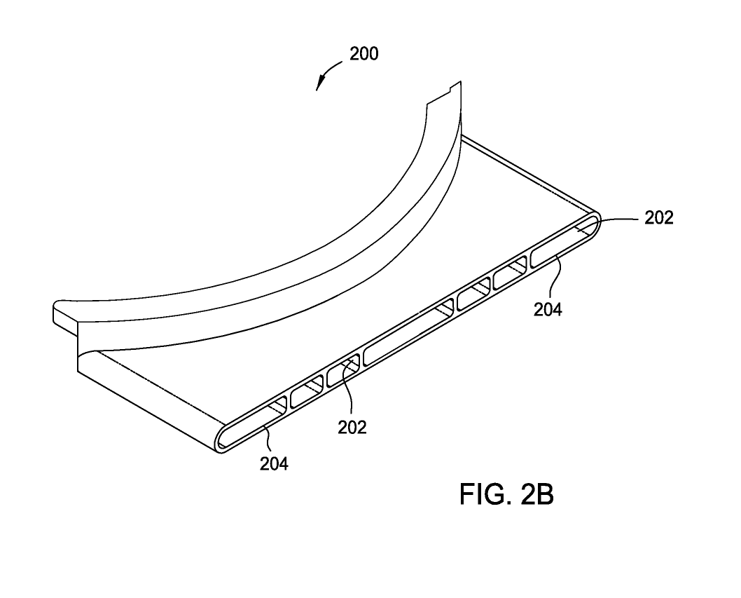

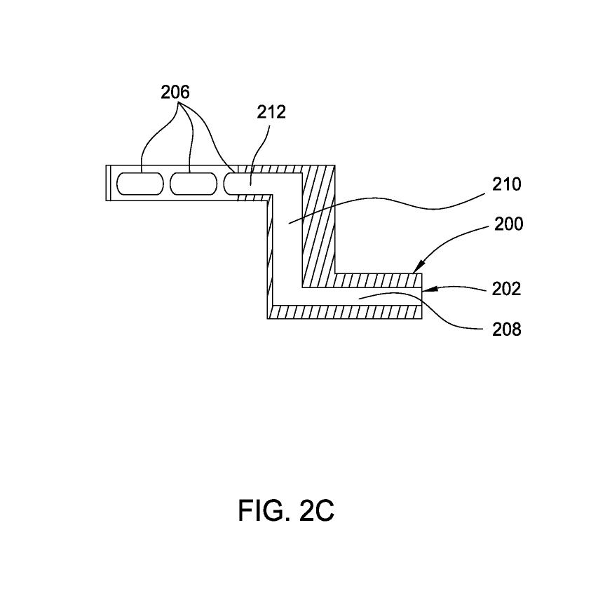

The liner assembly 163 is sized to be nested within or surrounded by an inner circumference of the base ring 136. The liner assembly 163 shields the metallic walls of the processing chamber 100 from the process gases used in processing. The metallic walls may react with the process gases and be damaged or introduce contamination into the processing chamber 100. While the liner assembly 163 is shown as a single body, in embodiments of the present disclosure, the liner assembly 163 comprises one or more liners and other components, as described below and shown in FIGS. 2-5.

According to one embodiment, the processing chamber 100 also includes one or more optical pyrometers 118, which measure temperatures within the processing chamber 100 and on the surface of substrate 108. A controller (not shown) controls electricity distribution from the electrical distribution board to the lamps 102. The controller also controls flows of cooling fluids within the processing chamber 100. The controller controls temperatures within the process chamber by varying the electrical voltage from the electrical distribution board to the lamps 102 and by varying the flows of cooling fluids.

A reflector 122 is placed outside the upper dome 128 to reflect infrared light radiating from the substrate 108 and upper dome 128 back into the processing chamber 100. The reflector 122 is secured to the upper dome 128 using a clamp ring 130. The reflector 122 has one or more connection ports 126 connected to a cooling fluid source (not shown). The connection ports 126 connect to one or more passages (not shown) within the reflector to allow cooling fluid (e.g., water) to circulate within the reflector 122.

According to one embodiment, the processing chamber 100 comprises a process gas inlet 174 connected to a process gas source 172. The process gas inlet 174 is configured to direct process gas generally across the surface of the substrate 108. The process chamber also comprises a process gas outlet 178 located on the side of the processing chamber 100 opposite the process gas inlet 174. The process gas outlet 178 is coupled to a vacuum pump 180.

According to one embodiment, the processing chamber 100 comprises a purge gas inlet 164 formed in the sidewall of the base ring 136. A purge gas source 162 supplies purge gas to the purge gas inlet 164. If the processing chamber 100 comprises a circular shield 167, the circular shield 167 is disposed between the process gas inlet 174 and the purge gas inlet 164. The process gas inlet 174, purge gas inlet 164, and process gas outlet 178 are shown for illustrative purposes, and the position, size, number of gas inlets and outlets, etc. may be adjusted to facilitate a uniform deposition of material on the substrate 108.

The substrate support is shown in a position to allow processing of a substrate in the process chamber. The central shaft 132, substrate support 106 or 107, and arms 134 may be lowered by an actuator (not shown). A plurality of lift pins 105 passes through the substrate support 106 or 107. Lowering the substrate support to a loading position below the processing position allows lift pins 105 to contact the lower dome 114, pass through holes in the substrate support 106 and the central shaft 132, and raise the substrate 108 from the substrate support 106. A robot (not shown) then enters the processing chamber 100 to engage and remove the substrate 108 though the loading port 103. The robot or another robot enters the process chamber through the loading port 103 and places an unprocessed substrate on the substrate support 106. The substrate support 106 then is raised to the processing position by the actuator to place the unprocessed substrate in position for processing.

According to one embodiment, processing of a substrate 108 in the processing chamber 100 comprises inserting the substrate through the loading port 103, placing the substrate 108 on the substrate support 106 or 107, raising the substrate support 106 or 107 and substrate 108 to the processing position, heating the substrate 108 by the lamps 102, flowing process gas 173 across the substrate 108, and rotating the substrate 108. In some cases, the substrate may also be raised or lowered during processing.

According to some aspects of the present disclosure, epitaxial processing in processing chamber 100 comprises controlling the pressure within the processing chamber 100 to be lower than atmospheric pressure. According to one embodiment, pressure within the processing chamber 100 is reduced to be between approximately 10 torr and 80 torr. According to another embodiment, pressure within the processing chamber 100 is reduced to be between approximately 80 torr and 300 torr. According to one embodiment, the vacuum pump 180 is activated to reduce the pressure of the processing chamber 100 before and/or during processing.

The process gas 173 is introduced into the processing chamber 100 from one or more process gas inlets 174, and exits the processing chamber 100 through one or more process gas outlets 178. The process gas 173 deposits one or more materials on the substrate 108 through thermal decomposition, for example, or other reactions. After depositing materials on the substrate 108, effluent (i.e., waste gases) 166, 175 are formed from the reactions. The effluent 166, 175 exits the processing chamber 100 through the process gas outlets 178.

When processing of a substrate 108 is complete, the process chamber is purged of process gas 173 and effluent 166, 175 by introducing purge gas 165 (e.g., hydrogen or nitrogen) through the purge gas inlets 164. Purge gas 165 may be introduced through the process gas inlets 174 instead of, or in addition to, the purge gas inlets 164. The purge gas 165 exits the process chamber through the process gas outlets 178.

Exemplary One-Piece Injector Assembly and Liner Assembly

In embodiments of the present disclosure, the process gas flows across the substrate in a plurality of parallel pathways. In one embodiment, one of the pathways intersects the central axis of the processing chamber 100. The process gas flows across the substrate at different rates in the different pathways, for example, the process gas flows fastest in a central pathway, with decreasing flow rates in pathways further from the central axis. Varying the flow rates of the process gas in the pathways improves thickness uniformity of a deposited layer as compared to a layer deposited by process gas flowing across the entire surface of the substrate at a single flow rate.

In some embodiments, the process gas that is supplied to the process chamber comprises multiple types of process gases, for example, a group III precursor gas (e.g., trimethylindium (In(CH₃)₃) and a group V precursor gas (e.g., phosphine (PH₃)). In some embodiments, the multiple process gases are supplied to the process chamber through separate process gas inlets. In some embodiments, the multiple process gases are supplied at a plurality of pressures.

FIGS. 2A and 2B illustrate isometric views of an exemplary one-piece injector assembly 200 that is used in the processing chamber 100 to supply one or more process gases to the process region 156, according to one embodiment of the disclosure. The one-piece injector assembly 200 is formed from quartz or other materials that are resistant to breakdown by process or purge gases and compatible with processing of a substrate. The one-piece injector assembly 200 may be formed from a single piece of material (e.g., a casting), or multiple pieces of material that are welded or otherwise joined to form a unitary structure (e.g., a construct) configured to prevent leaks between channels thereof. The one-piece injector assembly 200 has a plurality (e.g. in this embodiment, seven, although other numbers from two to thirty-seven are contemplated) of channels 202 within the one-piece injector assembly 200. The one-piece injector assembly 200 has a first arc-shaped surface 214 with one or more process gas inlets 206 through the arc-shaped surface 214. The one-piece injector assembly 200 may also have a second arc-shaped surface 216 that has a radius concentric to the first arc-shaped surface 214.

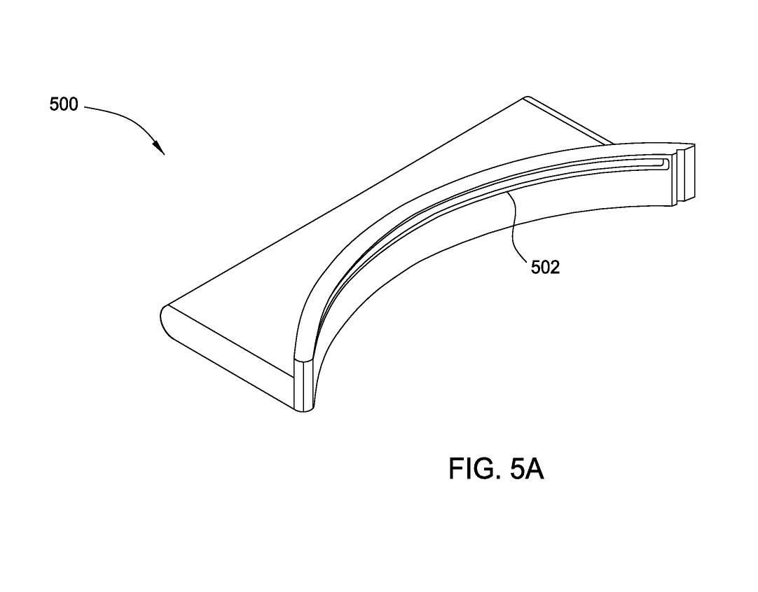

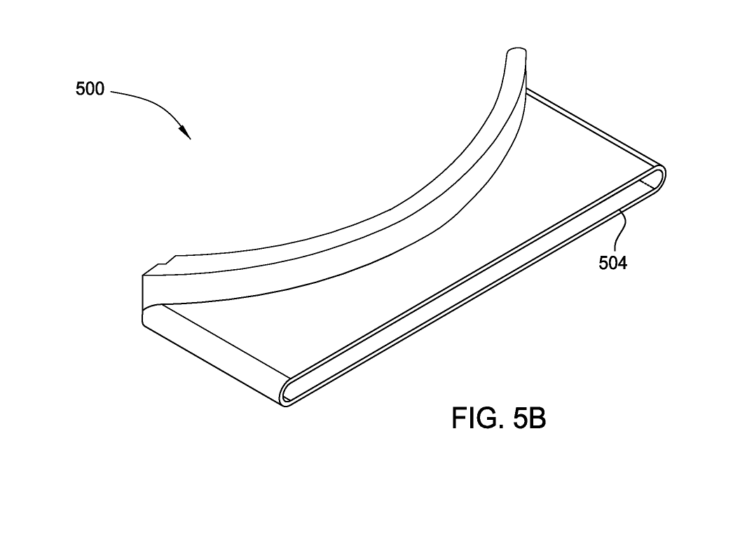

FIG. 2C illustrates a cross-sectional view of the exemplary one-piece injector assembly 200. Each channel 202 comprises an injector inlet passage 208, a transition passage 210, and a process gas inlet passage 212. The channels 202 each connect an injector inlet 204 (see FIG. 2B) with a process gas inlet 206 via the corresponding injector inlet passage 208, transition passage 210, and process gas inlet passage 212. In some embodiments, the channels 202 extend in parallel to one another. In some embodiments, the process gas inlet passages 212 leading to the process gas inlets 206 are also parallel to a plane of the substrate support 106 (see FIGS. 1 and 5).

In some embodiments, process gas is supplied to the injector inlets 204 in separate streams at a plurality of pressures and/or flow rates by the process gas source 172. The separate channels 202 of the one-piece injector assembly 200 enable the separate streams of process gas to enter the processing chamber 100 through the process gas inlets 206 at a plurality of pressures and/or flow rates. The flow rate of process gas across the surface of the substrate 108 may be affected by the pressure of the process gas when entering the processing chamber 100. By maintaining the separate streams of process gas, the separate channels of the one-piece injector assembly 200 enable the process gas to flow across the substrate at differing flow rates in different regions. For example, process gas supplied to the process chamber through a central process gas inlet may be supplied at a higher flow rate and/or pressure than process gas supplied to a process gas inlet other than the central process gas inlet. The arc-shaped surface 208 may enable each of the process gas inlets 206 to be at a same distance from a substrate 108 being processed in a processing chamber 100.

In some embodiments, the process gas comprises a mixture of multiple process gases. The separate channels 202 of the one-piece injector assembly 200 enable the multiple types of process gases to enter the processing chamber 100 through the process gas inlets 206 without mixing before entering the processing chamber 100, by, for example, introducing different gases in alternating channels across the plane of the substrate.

According to certain embodiments, the one-piece injector assembly 200 is combined with a liner assembly (e.g., an upper liner and a lower liner) configured to ease installation of the one-piece injector assembly 200 in processing chamber 100.

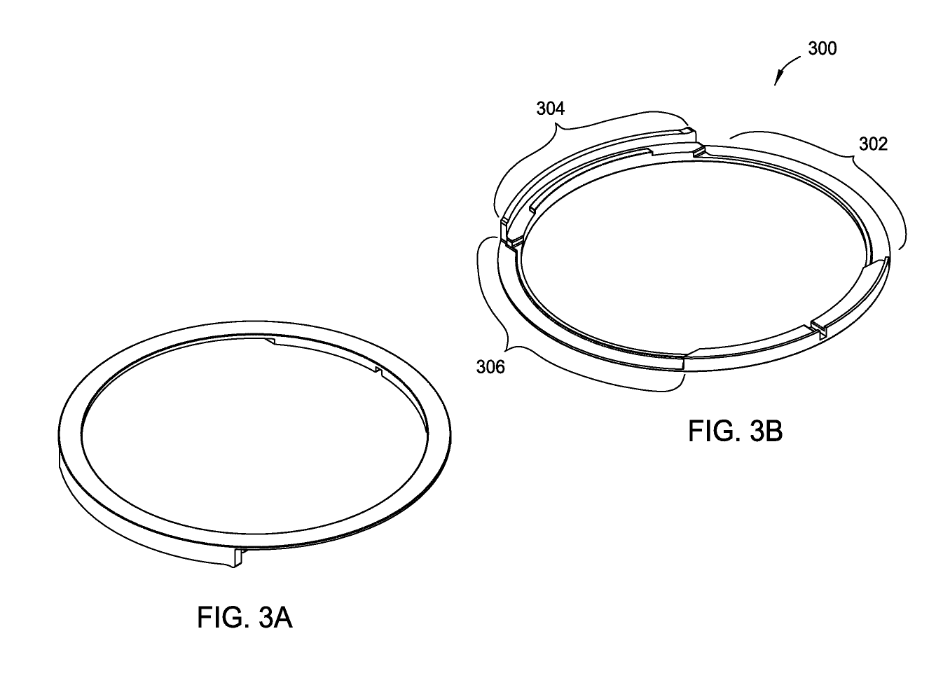

FIGS. 3A and 3B illustrate isometric views of an exemplary upper liner 300 that may be used in the processing chamber 100 in order improve ease of installation of the one-piece injector assembly 200, according to certain embodiments. The upper liner 300 is formed from quartz or other materials that are resistant to breakdown by process or purge gases and compatible with processing of a substrate. The upper liner 300 is used as part of, or as a replacement for part of, liner assembly 163. The upper liner 300 has a portion thereof “cutaway”, i.e., removed, as cut-away portion 302 to accommodate a one-piece injector assembly 200 when assembled with the one-piece injector assembly in processing chamber 100. The upper liner 300 has a portion 304 that is thicker in a vertical direction (e.g., parallel to the axis of the central shaft 132 of the processing chamber 100) and is configured to line a region of the process chamber adjacent to a cut-out portion of a lower liner. In one embodiment, the upper liner 300 has a second cut-away portion 306 that may align with a one-piece exhaust gas liner having process gas outlets and installed in processing chamber 100.

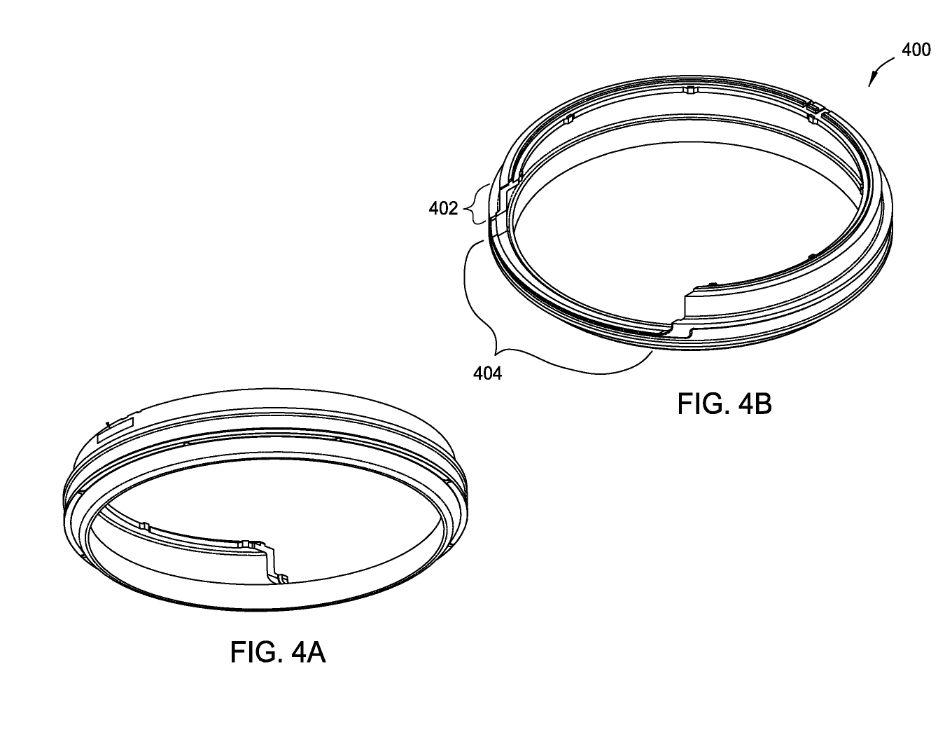

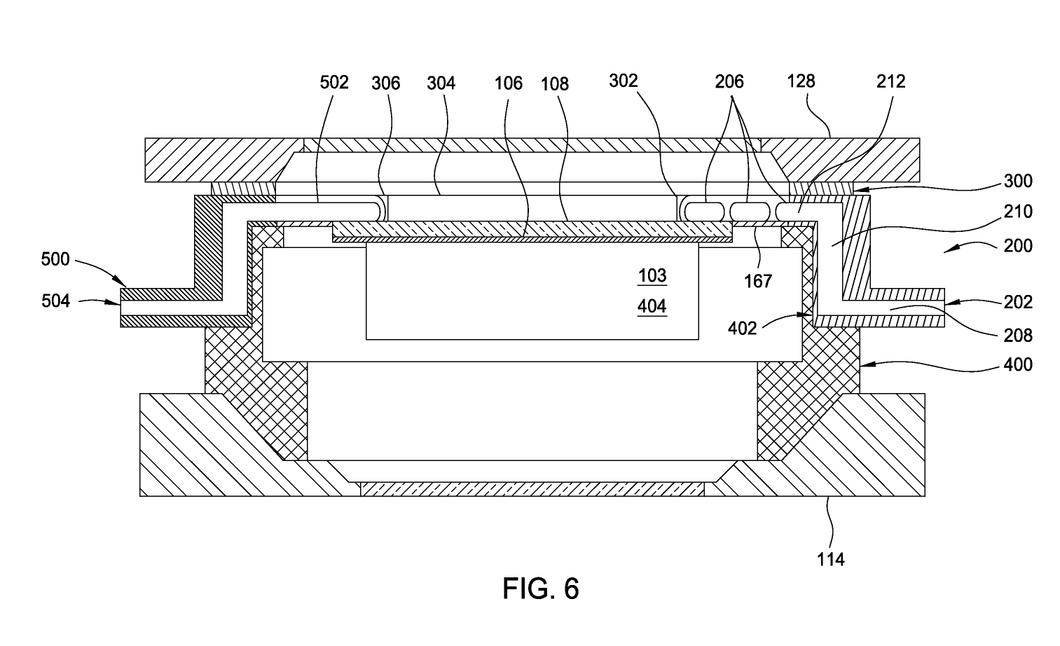

FIGS. 4A and 4B illustrate isometric views of an exemplary lower liner 400 that may be used in the processing chamber 100 in order improve ease of installation of the one-piece injector assembly 200, according to certain embodiments. The lower liner 400 is formed from quartz or other materials that are resistant to breakdown by process or purge gases and compatible with high temperature processing of a substrate. The lower liner 400 is used as part of, or as a replacement for part of, liner assembly 163. The lower liner 400 has a first portion 402 that has a smaller diameter than the remainder of the lower liner 400. The smaller diameter of the portion 402 accommodates rotating the lower liner 400 within the processing chamber 100 when the one-piece injector assembly 200 has been installed in the processing chamber 100 (see FIG. 6). The lower liner 400 has a cut-away portion 404 that is sized to match loading port 103. The described configuration allows lower liner 400 to be rotated within the processing chamber 100 to accommodate installation of the one-piece injector assembly 200 through the cut-away portion 404. The described configuration also allows installation of one or more exhaust liners through the cut-away portion 404. Finally, the lower liner 400 may be rotated within the processing chamber 100, after installation of the one-piece injector assembly and any exhaust liners, to align the cut-away portion 404 with the loading port 103.

FIGS. 5A and 5B illustrate isometric views of an exemplary one-piece exhaust liner 500 that is used in the processing chamber 100 to allow effluent to be removed from the processing chamber 100, according to one embodiment of the disclosure. The one-piece exhaust liner 500 is formed from quartz or other materials that are resistant to breakdown by effluent gases and compatible with processing of a substrate. The one-piece exhaust liner 500 may be formed from a single piece of material (e.g., a casting), or multiple pieces of material that are welded or otherwise joined to form a unitary structure (e.g., a construct) configured to prevent leaks. The one-piece exhaust liner 500 has a process gas outlet 502 connected with an exhaust liner outlet 504 via a channel through the one-piece exhaust liner 500.

FIG. 6 illustrates a partial cross-sectional view of one-piece injector assembly 200, upper liner 300, lower liner 400, and one-piece exhaust liner 500 assembled in a process chamber, such as processing chamber 100 in FIGS. 1A and 1B. Base ring 136 is omitted from FIG. 6 to allow a clearer view of other components. The one-piece injector assembly 200 is used to supply one or more fluids, such as a process gas, to the process region 156 of processing chamber 100. As described above, the central axis of each process gas inlet passage 212 leading to the corresponding process gas inlet 206 is generally parallel to a plane of the substrate support 106. Each process gas inlet passage 212 leading to the corresponding process gas inlet 206 is also generally parallel to a plane of the surface of the substrate.

The upper liner 300 is assembled together with the one-piece injector assembly 200 by aligning the one-piece injector assembly with the cut-away portion 302 of the upper liner 300 as the upper liner 300 is installed into the processing chamber 100. A thicker portion 304 of the upper liner 300 aligns with a cut-away portion 404 of the lower liner 400 to protect the processing chamber 100 wall from exposure to process gases while allowing use of loading port 103 for access to the interior of processing chamber 100. The upper liner 300, one-piece injector assembly 200, one-piece exhaust liner 500, and lower liner 400 are installed between the upper dome 128 and the lower dome 114 in the processing chamber 100. As described above, the cut-away portion 404 of the lower liner 400 is at an angle of approximately 90° from the channels 202 of one-piece injector assembly 200 when the one-piece injector assembly 200 and lower liner 400 are installed in the processing chamber 100. As shown in FIG. 6, the cut-away portion 404 of the lower liner 400 is aligned with the loading port 103 of the processing chamber 100, when installed.

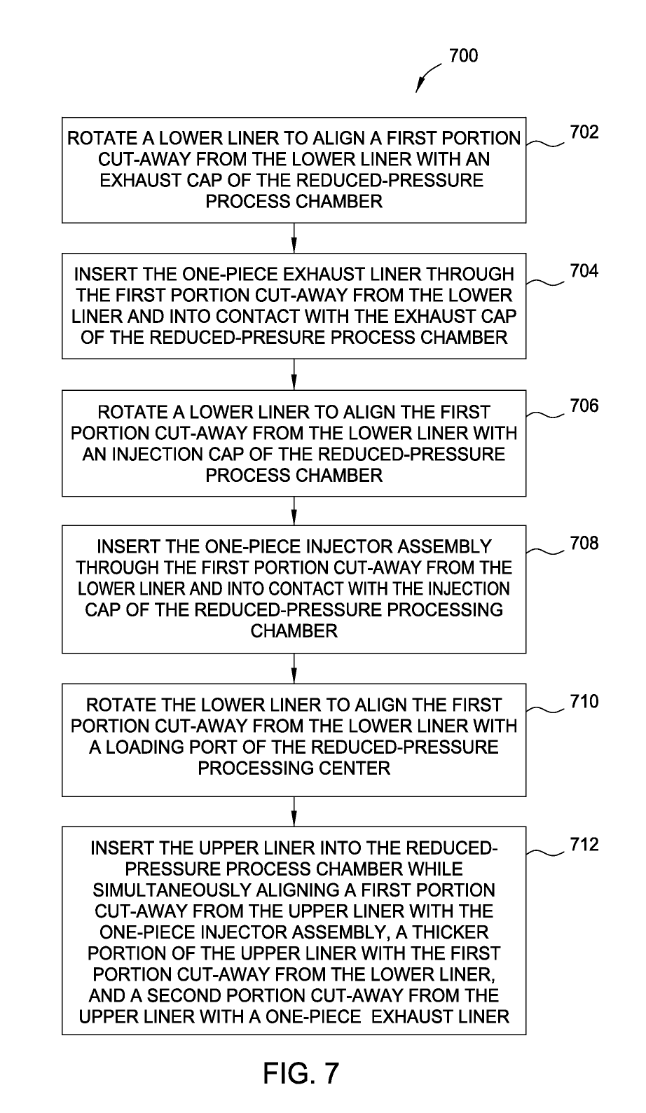

FIG. 7 sets forth an exemplary operation 700 for installing a one-piece injector assembly (e.g., one-piece injector assembly 200) and a one-piece exhaust liner (e.g., one-piece exhaust liner 500) into a reduced-pressure processing chamber (e.g., reduced-pressure processing chamber 100) comprising an upper liner (e.g., upper liner 300) and a lower liner (e.g., lower liner 400). Operation 700 may be performed by one or more process chamber operators, for example. Operation 700 begins at block 702 by a processing chamber operator, for example, rotating a lower liner to align a first portion cut-away (e.g., cut-away portion 404) from the lower liner with an exhaust cap of the reduced-pressure processing chamber. At block 704, the process chamber operator, for example, inserts the one-piece exhaust liner through the first portion cut-away from the lower liner and into contact with the exhaust cap of the reduced-pressure process chamber. At block 706, the process chamber operator, for example, rotates the lower liner to align the first portion cut-away (e.g., cut-away portion 404) from the lower liner with an injection cap of the reduced-pressure processing chamber. At block 708, the process chamber operator, for example, inserts the one-piece injector assembly through the first portion cut-away from the lower liner and into contact with the injection cap of the reduced-pressure process chamber. At block 710, the process chamber operator, for example, rotates the lower liner (for example, approximately 90°) to align the first portion cut-away from the lower liner with a loading port (e.g., loading port 103) of the reduced-pressure process chamber. At block 712, the process chamber operator, for example, inserts the upper liner into the reduced-pressure process chamber while simultaneously aligning a first portion cut-away (e.g., cut-away portion 302) from the upper liner with the one-piece injector assembly, a thicker portion (e.g., thicker portion 304) of the upper liner with the first portion cut-away (e.g., cut-away portion 404) from the lower liner, and a second portion cut-away (e.g., cut-away portion 306) from the upper liner with the one-piece exhaust liner.

While FIG. 6 shows a single injector assembly 200 installed in a reduced-pressure process chamber and FIG. 7 sets forth an operation for installing a single injector assembly in a reduced-pressure process chamber, the present disclosure is not so limited. According to some embodiments, a plurality (e.g., two) of one-piece injector assemblies may be installed in a reduced-pressure process chamber and used to flow process gas and/or purge gas across a substrate in a plurality of pathways during processing of the substrate. According to these embodiments, the process gas inlet passages 212 of the plurality of one-piece injector assemblies 200 are parallel to each other when the one-piece injector assemblies 200 are installed in a reduced-pressure process chamber. As described above, the process gas inlet passages 212 of the plurality of one-piece injector assemblies are also generally parallel to a surface of the substrate when the one-piece injector assemblies 200 are installed in a reduced-pressure process chamber.

According to one embodiment, processing of a substrate 108 in the processing chamber 100 using the one-piece injector assembly 200 is similar to processing in the processing chamber 100 described above. Processing of a substrate 108 in the processing chamber 100 using the one-piece injector assembly 200 may comprise inserting the substrate through the loading port 103, placing the substrate 108 on the substrate support 106 or 107, raising the substrate support 106 or 107 and substrate 108 to the processing position, heating the substrate 108 by the lamps 102, flowing process gas 173 across the substrate 108, and rotating the substrate 108. In some cases, the substrate may also be raised or lowered during processing.

In the case of performing epitaxial deposition using a single type of process gas in processing chamber 100 using the one-piece injector assembly 200, the single type of process gas is supplied to each of the injector inlets 204 by an injection cap. Referring again to FIGS. 2A, 2B, 2C, the single type of process gas may be supplied at a different pressure and/or flow rate to each of the injector inlets 204. The process gas supplied to each injector inlet 204 flows through the corresponding injector inlet passage 208, the corresponding transition passage 210, and the corresponding process gas inlet passage 212. The process gas exits the one-piece injector assembly through the process gas inlets 206. The pressure and flow rate of the process gas in each channel 202 is independent of the pressure and flow rate of the process gas in every other channel 202. Thus, if the process gas is supplied at different pressures or flow rates to the injector inlets 204, then the process gas exits the one-piece injector assembly and enters the process region 156 of the processing chamber 100 from each process gas inlet 206 at a different pressure or flow rate.

Upon exiting the process gas inlets 206 of the one-piece injector assembly, the process gas flows across and parallel to the upper surface of the substrate. As described above, the process gas inlet passages are generally parallel to the upper surface of the substrate, causing the process gas to flow parallel to the upper surface of the substrate in a laminar flow pattern. Supplying the process gas at a higher flow rate across the center of the substrate improves the thickness uniformity of a deposited layer from epitaxial deposition, as compared to a deposited layer from flowing process gas across the entire substrate at a single flow rate.

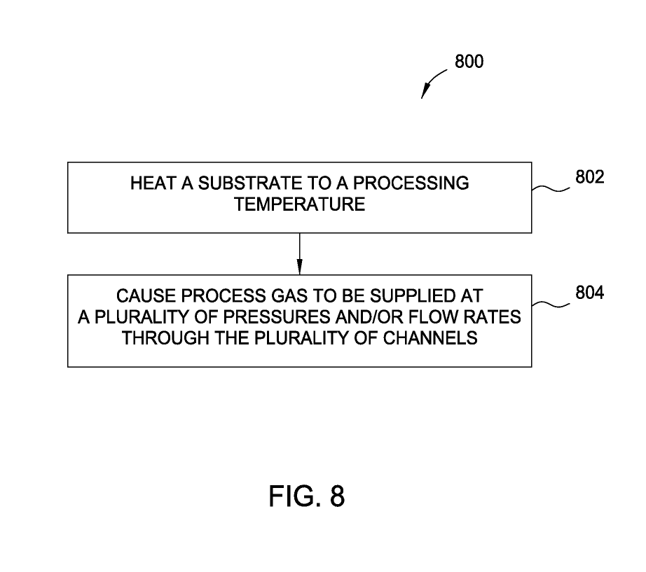

FIG. 8 illustrates an exemplary operation 800 for performing epitaxial deposition in a processing chamber 100 using a one-piece injector assembly 200 comprising a plurality of channels. Operation 800 may be performed by one or more controllers, for example. A controller, for example, begins operation 800 at block 802 by heating a substrate to a processing temperature, for example 250-800° C. or 300-750° C. At block 804, the controller causes process gas to be supplied at a plurality of pressures and/or flow rates through the plurality of channels.

In the case of performing epitaxial deposition using multiple types of process gas in processing chamber 100 using the one-piece injector assembly 200, a mixture of the multiple types of process gas is supplied to each of the injector inlets 204 by an injection cap. Referring again to FIGS. 2A, 2B, 2C, the mixed process gas may be supplied at different pressures and/or flow rates to each of the injector inlets 204. In addition, the mixtures of process gas supplied to each of the injector inlets 204 may have differing mix ratios. The process gas supplied to each injector inlet 204 flows through the corresponding injector inlet passage 208, the corresponding transition passage 210, and the corresponding process gas inlet passage 212. The process gas exits the one-piece injector assembly through the process gas inlets 206. The pressure and flow rate of the process gas in each channel 202 is independent of the pressure and flow rate of the process gas in every other channel 202. In addition, the independent channels 202 do not allow mixing of the flows of process gas before the process gas enters the process chamber. Thus, if the process gas is supplied at different pressures, flow rates, and/or mix ratios to the injector inlets 204, then the process gas exits the one-piece injector assembly and enters the process region 156 of the processing chamber 100 from each process gas inlet 206 at a different pressure, flow rate, and/or mix ratio.

Upon exiting the process gas inlets 206 of the one-piece injector assembly, the process gas flows across and parallel to the upper surface of the substrate. As described above, the process gas inlet passages are generally parallel to the upper surface of the substrate, which causes the process gas to flow parallel to the upper surface of the substrate in a laminar flow pattern. Preventing the flows of process gas from mixing before entering the process chamber improves the thickness uniformity of a deposited layer from epitaxial deposition.

A system controller (not shown) can be used to regulate the operations of the processing chamber 100. The system controller can operate under the control of a computer program stored on a hard disk drive of a computer. For example, the computer program can dictate the process sequencing and timing, mixture of gases, chamber pressures, RF power levels, susceptor positioning, slit valve opening and closing, and other parameters of a particular process.

To provide a better understanding of the foregoing discussion, the above non-limiting examples are offered. Although the examples may be directed to specific embodiments, the examples should not be interpreted as limiting the disclosure in any specific respect.

While the foregoing is directed to embodiments of the present disclosure, other and further embodiments of the disclosure may be devised without departing from the basic scope thereof, and the scope thereof is determined by the claims that follow.

What is claimed is:

1. An injector assembly, comprising:
a one-piece construct having multiple independent channels therethrough by which one or more fluids may be flowed therethrough and into a processing chamber.

2. The injector assembly of claim 1, wherein multiple pieces of material are welded together to form the one-piece construct.

3. The injector assembly of claim 1, wherein the one-piece construct comprises a casting.

4. The injector assembly of claim 1, wherein the one-piece construct has an arc-shaped surface which has one or more process gas inlet passages formed therein.

5. The injector assembly of claim 1, wherein the multiple independent channels comprise process gas inlet passages and each process gas inlet passage is parallel to every other process gas inlet passage.

6. The injector assembly of claim 1, wherein the injector assembly comprises quartz.

7. A lower liner for a processing chamber, comprising:
a ring-shaped body configured with a first portion of a first diameter and a second portion of a second diameter smaller than the first diameter to allow rotation of the lower liner past an injector assembly during installation of the lower liner and the injector assembly in the processing chamber.

8. The lower liner of claim 7, wherein the ring-shaped body is formed from multiple pieces.

9. The lower liner of claim 7, wherein the ring-shaped body comprises quartz.

10. An apparatus for processing a substrate, comprising:
a processing chamber body;
a process fluid supply;
a vacuum pump coupled with the processing chamber body;
a susceptor; and
an injector assembly, coupled with the process gas supply, wherein the injector assembly comprises a one-piece construct having multiple independent channels therethrough by which one or more process fluids from the process fluid supply may be flowed therethrough and into the processing chamber.

11. The apparatus of claim 10, wherein multiple pieces of material are welded together to form the one-piece construct.

12. The apparatus of claim 10, wherein the one-piece construct comprises a casting.

13. The apparatus of claim 10, wherein the multiple independent channels comprise process gas inlet passages and the process gas inlet passages are parallel to a plane of the susceptor.

14. The apparatus of claim 10, wherein the multiple independent channels comprise process gas inlet passages and each process gas inlet passage is parallel to every other process gas inlet passage.

15. The apparatus of claim 10, wherein the injector assembly comprises quartz.

16. The apparatus of claim 10, further comprising:
a lower liner comprising a ring-shaped body configured with a first portion of a first diameter and a second portion of a second diameter smaller than the first diameter to allow rotation of the lower liner past the injector assembly during installation of the lower liner and the injector assembly in the processing chamber.

17. The apparatus of claim 16, wherein the ring-shaped body is formed from multiple of pieces.

18. The apparatus of claim 16, wherein the ring-shaped body comprises quartz.
